(19) United States
(12) Patent Application Publication
(10) Pub. No.: US 2011/0083892 A1
(43) Pub. Date: Apr. 14, 2011

(54) ELECTRONIC COMPONENT-EMBEDDED PRINTED CIRCUIT BOARD AND METHOD OF MANUFACTURING THE SAME

(76) Inventors: Hong Bok WE, Gyunggi-do (KR); Tae Sung Jeong, Gyunggi-do (KR); Dae Jun Kim, Gyunggi-do (KR)

(21) Appl. No.: 12/631,578

(22) Filed: Dec. 4, 2009

(30) Foreign Application Priority Data
Oct. 12, 2009 (KR) 10-2009-0096916

(51) Int. Cl. H05K 1/18; C23C 14/48

(52) U.S. Cl. 174/260; 204/192.11

(57) ABSTRACT

Disclosed is an electronic component-embedded printed circuit board, which includes an insulating base, an insulating layer formed on one surface of the insulating base, an electronic component embedded in the insulating layer so that an active surface of the electronic component having a connection terminal faces the insulating base, a trench formed in the insulating base to expose the connection terminal, and a connection pattern formed and embedded in the trench, and in which the embedded connection pattern is finely formed by an imprinting process and is connected to the connection terminal of the electronic to component, thus obviating a need for an additional redistribution layer and reducing the manufacturing cost. A method of manufacturing such a printed circuit board is also provided.

### CROSS REFERENCE TO RELATED APPLICATION

This application claims the benefit of Korean Patent Application No. 10-2009-0096916, filed Oct. 12, 2009, entitled “A Printed Circuit Board Comprising Embedded Electronic Component Within and A Method For Manufacturing The Same”, which is hereby incorporated by reference in its entirety into this application.

### BACKGROUND OF THE INVENTION

1. Technical Field

The present invention relates to an electronic component-embedded printed circuit board and a method of manufacturing the same.

2. Description of the Related Art

In order to manufacture printed circuit boards (PCBs) adapted for semiconductor packages which are required to have a reduced profile and a variety of functions, a variety of techniques are in demand.

For example, in the fabrication of an FCBGA (Flip Chip Ball Grid Array) package, electrical conductive terminals or lands of IC components are directly soldered to the corresponding land of a die bonding region on the surface of a substrate using reflowable solder bumps or balls. As such, the electronic component or components may be functionally connected to the other device of an electronic system via a layer of an electrical conductive path including a substrate trace. The substrate trace typically transports signals which are being transmitted between electronic components such as ICs of the system. In the case of the FCBGA, the IC located at the upper end of the substrate and the capacitor located at the lower end of the substrate may be surface-mounted. In this case, the path of a circuit, namely, the length of a connection circuit, which is used to connect the IC and the capacitor, is made longer in proportion to the thickness of the substrate, and thus the impedance is raised, negatively affecting electrical performance. Also, because a predetermined area of the lower surface of the substrate must be used for chip mounting, the requirement of a user who wants to construct a ball array on, for example, the entire lower surface of the substrate cannot be met. Like this, the degree of freedom with which the substrate can be designed is limited.

With the goal of solving this problem, a component embedding technique which inserts the component into the substrate so as to reduce the path of the circuit is becoming more popular. This embedded PCB is configured such that active/passive electronic components which have been conventionally mounted in the form of a package on a substrate are embedded within an organic substrate, thus ensuring a predetermined surface area to thereby achieve multi-functionality and also minimizing a signal transmission line to thereby cope with high-frequency low loss/high efficiency technology and meet expectations vis-a-vis product miniaturization, leading to a kind of next-generation three-dimensional packaging technique and a novel type of highly functional packaging trend.

FIGS. 1A to 1E sequentially show a process of manufacturing an electronic component-embedded PCB according to a conventional technique. With reference thereto, the problems of the conventional technique are described below.

First, as shown in FIG. 1A, a substrate body 10 is prepared, which includes an insulating base 3 having a cavity 2 for disposing an electronic component 1 therein and a tape 4 attached to one surface of the insulating base 3.

Next, as shown in FIG. 1B, the electronic component 1 is disposed in the cavity 2 of the insulating base 3. As such, the electronic component 1 is disposed in the cavity 2 using a vacuum adsorption head (not shown) and is supported by the tape 4.

Next, as shown in FIG. 1C, an insulating layer 5 is formed on the substrate body 10 including the cavity 2. As the insulating layer 5 is formed inside the cavity 2 in which the electronic component 1 is disposed, the electronic component 1 is embedded in the insulating layer 5.

Next, as shown in FIG. 1D, the tape 4 is removed. The tape 4, which was used to support the electronic component 1 until before the electronic component 1 is fixed to the substrate body 10 by the insulating layer 5, is removed after the insulating layer 5 is formed.

Next, as shown in FIG. 1E, an insulating layer 5 is further formed on the one surface of the insulating base 3 from which the tape 4 was removed, so that the electronic component 1 is embedded in the substrate body 10, and a circuit layer 8 including vias 6 and a circuit pattern 7 is formed. The vias 6 are electrically connected to connection terminals 9 of the electronic component 1.

As mentioned above, the conventional technique involves the process of forming the cavity 2 for disposing the electronic component 1 in the substrate body 10. However, this process consumes a long period of time and is expensive, and also makes precise disposition to of the electronic component 1 inside the cavity 2 difficult. Furthermore, after the electronic component 1 is disposed inside the cavity 2, the remainder of the cavity 2 may not be completely filled with the insulating layer 5, and thus there may occur a concern about the formation of voids.

Furthermore, in order to expose the connection terminals 9, via holes may be processed in the insulating layer 5 using a laser, which is undesirably expensive. Moreover, upon the formation of the via holes, the electronic component 1 may be undesirably penetrated by the laser. Because the connection terminals 9 of the electronic component 1 are connected to the circuit of the substrate body 10 by means of the via holes processed using the laser, the number of I/O pads of the electronic component 1 which may be embedded and the pitches thereof are undesirably limited.

In addition, there is a need for a redistribution layer in order to connect the connection terminals 9 of the electronic component 1 to the circuit of the substrate body 10, undesirably incurring problems in which the degree of freedom with which the PCB may be designed is decreased and the manufacturing cost is increased.

### SUMMARY OF THE INVENTION

Accordingly, the present invention has been made keeping in mind the problems encountered in the related art and the present invention is intended to provide an electronic component-embedded PCB and a method of manufacturing the same, in which there is no need to process a cavity for disposing an electronic component in an insulating layer, thus simplifying the manufacturing process and reducing the manufacturing cost, and furthermore in which an embedded connection pattern which is connected to connection terminals of an electronic component is formed by an imprinting process, thus obviating a need for an additional redistribution layer.

An aspect of the present invention provides an electronic component-embedded PCB, including an insulating base, an insulating layer formed on one surface of the insulating base, an electronic component embedded in the insulating layer so that an active surface of the electronic component having a connection terminal faces the insulating base, a trench formed in the insulating base to expose the connection terminal, and a connection pattern formed and embedded in the trench.

In this aspect, the trench may be formed by rotating a cylindrical mold.

In this aspect, the PCB may further include an adhesive layer formed between the insulating base and the electronic component.

As such, the adhesive layer may include a solid die attach film or a liquid adhesive.

In this aspect, the PCB may further include a build-up layer formed on an exposed surface of the insulating base or an exposed surface of the insulating layer.

In this aspect, a thickness ranging from the active surface of the electronic component to an exposed surface of the insulating base may be equal to a thickness ranging from a surface opposite the active surface to an exposed surface of the insulating layer.

Another aspect of the present invention provides a method of manufacturing the electronic component-embedded PCB, including (A) mounting an electronic component in a face down manner on one surface of an insulating base, (B) forming an insulating layer on the one surface of the insulating base so that the electronic component is embedded, (C) processing a trench in the insulating base so as to expose a connection terminal of the electronic component, and (D) subjecting the trench to plating, so that a connection pattern which is connected to the connection terminal is formed and embedded in the trench.

In this aspect, processing the trench in (C) may be performed by rotating a cylindrical mold.

In this aspect, mounting the electronic component in (A) may be performed by forming an adhesive layer on the one surface of the insulating base and then adhering the electronic component to the adhesive layer.

As such, the adhesive layer may include a solid die attach film or a liquid adhesive.

In this aspect, the method may further include forming a build-up layer on an exposed surface of the insulating base or an exposed surface of the insulating layer, after (D).

In this aspect, the method may further include forming the insulating base on a carrier so as to expose the one surface of the insulating base, before (A), and removing the carrier, after (B).

In this aspect, forming the insulating layer in (B) may be performed by applying the to insulating layer on the insulating base so that a thickness ranging from an active surface of the electronic component to an exposed surface of the insulating base is equal to a thickness ranging from a surface opposite the active surface to an exposed surface of the insulating layer.

### BRIEF DESCRIPTION OF THE DRAWINGS

The features and advantages of the present invention will be more clearly understood from the following detailed description taken in conjunction with the accompanying drawings, in which:

FIGS. 1A to 1E are cross-sectional views sequentially showing a process of manufacturing an electronic component-embedded PCB according to a conventional technique;

FIGS. 2 and 3 are cross-sectional views showing electronic component-embedded PCBs according to embodiments of the present invention; and

FIGS. 4 to 11 are cross-sectional views sequentially showing a process of manufacturing the electronic component-embedded PCB according to the embodiment of the present invention.

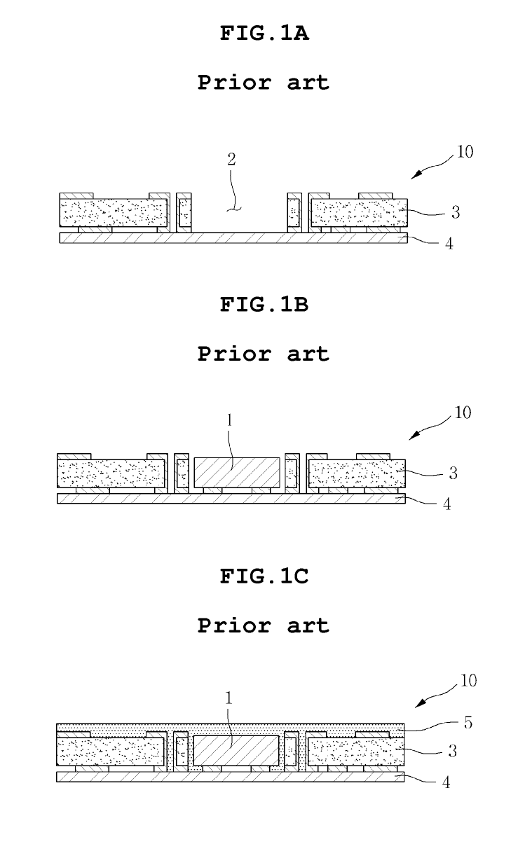

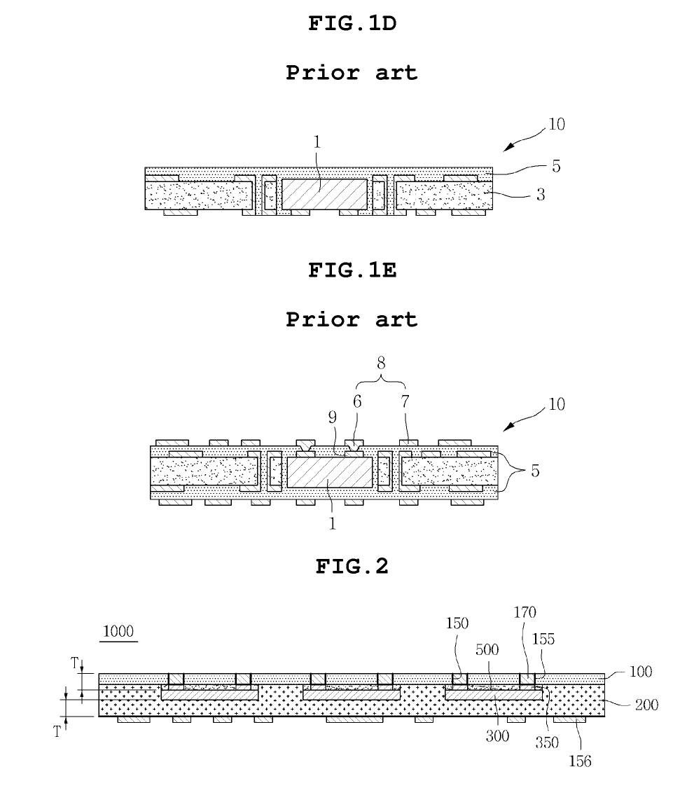

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. In the description, the terms “one surface”, “exposed surface” and so on are used to distinguish one element from another element, and the elements are not defined by the above terms. Moreover, descriptions of known techniques, even if they are pertinent to the present invention, are regarded as to unnecessary and may be omitted in so far as they would make the characteristics of the invention unclear and render the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

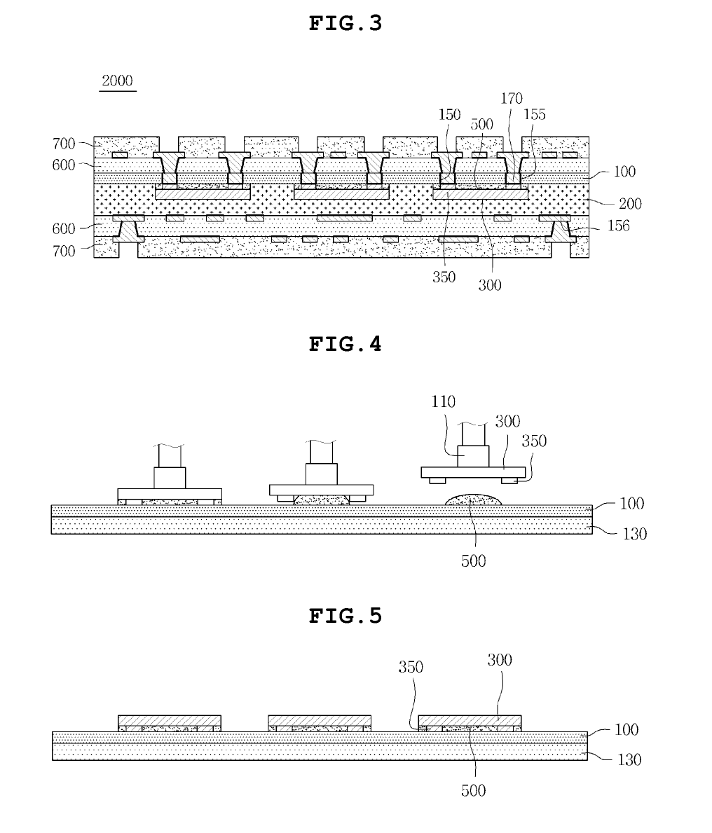

FIGS. 2 and 3 are cross-sectional views showing electronic component-embedded PCBs according to embodiments of the present invention.

As shown in FIGS. 2 and 3, the electronic component-embedded PCB 1000 according to the present embodiment includes an insulating base 100, an insulating layer 200 formed on one surface of the insulating base 100, an electronic component 300 embedded in the insulating layer 200 so that an active surface thereof having connection terminals 350 faces the insulating base 100, trenches 150 formed in the insulating base 100 to expose the connection terminals 350, and a connection pattern 170 formed and embedded in the trenches 150 (FIG. 2). In addition, the electronic component-embedded PCB 2000 may further include a build-up layer 600 formed on the exposed surface of the insulating base 100 or the exposed surface of the insulating layer 200 (FIG. 3).

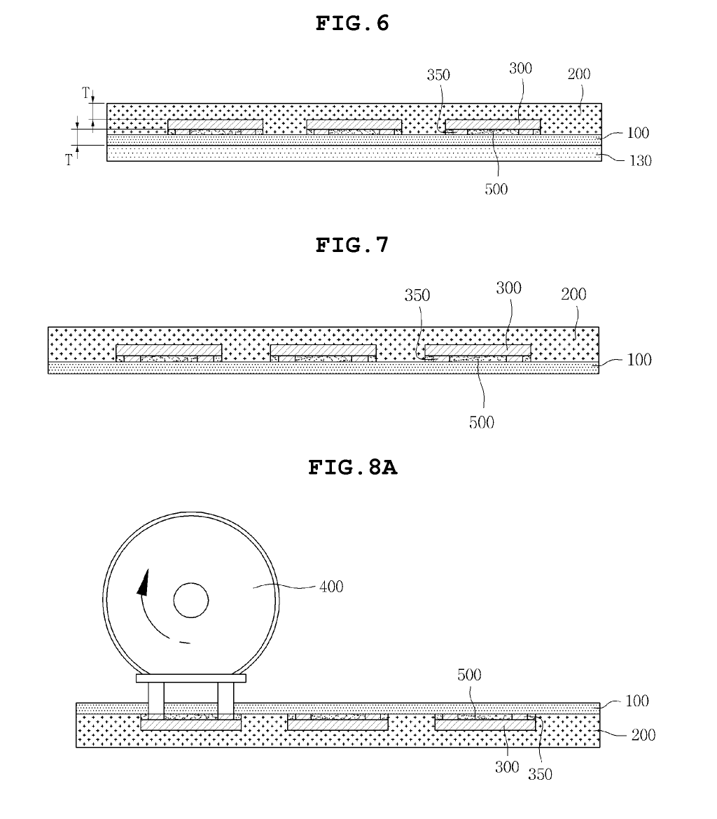

The insulating layer 200 is used to embed the electronic component 300 therein, and is formed on one surface of the insulating base 100. As such, the insulating layer 200 and the insulating base 100 may be formed using an epoxy-based resin which is typically useful in a packaging process. On the other hand, in the course of embedding the electronic component 300, the insulating layer 200 is formed on the insulating base 100 (FIG. 6). As such, although the insulating layer 200 may be applied in a state of being semi-cured on the insulating base 100, it is desirable to apply the insulating layer 200 using a liquid coating process in order to protect the electronic component 300 from damage. Moreover, in order to achieve the structural stability of the PCB, the insulating layer 200 is formed on the insulating base 100 so that a thickness T ranging from the active surface of the electronic component 300 to the exposed surface of the insulating base 100 is equal to a thickness T ranging from the surface opposite the active surface to the exposed surface of the insulating layer 200. Herein, the equal thicknesses do not mean that their mathematical values are completely identical to each other but are used in a sense which takes into account slight changes in thickness due to process error and so on occurring in the manufacturing process. Furthermore, in the course of embedding the electronic component 300 in the insulating layer 200 according to the present embodiment, a cavity for disposing the electronic component 300 is not formed in the insulating layer 200 unlike the conventional technique, thus simplifying the manufacturing process according to the present invention and reducing the manufacturing cost.

The electronic component 300 is mounted on the insulating base 100 so that its active surface faces the insulating base 100 (a face down manner; FIG. 5), after which the insulating layer 200 is applied (FIG. 6), so that the electronic component 300 is embedded in the PCB. When the electronic component 300 is mounted, an adhesive layer 500 may be interposed between the insulating base 100 and the electronic component 300 in order to fix the electronic component 300. As such, the adhesive layer 500 may be formed of a solid die attach film or a liquid adhesive. The electronic component 300 is electrically connected to the PCB so as to perform a predetermined function, and examples thereof include a capacitor device or a semiconductor device.

The trenches 150 may be formed in the insulating base 100 so as to expose the connection terminals 350 of the electronic component 300. A process for forming the trenches 150 is not particularly limited as long as it is known in the art, and may include for example an imprinting process or a laser process (e.g. Nd—YAG (Neodymium-doped Yttrium Aluminum Garnet). In the case where a flat mold is used in the imprinting process, such a flat mold is not easy to strip from the insulating base 100. Thus, the trenches 150 may be formed by rotating a cylindrical mold 400 which is easy to strip.

When the imprinting process is used, a plurality of trenches 150 may be simply formed. Furthermore, even when two or more electronic components 300 are mounted, trenches 150 may be accurately formed at positions corresponding to respective connection terminals 350.

The connection pattern 170 is formed by filling the trenches 150, and is connected to to the connection terminals 350 of the electronic component 300. The connection pattern 170 may be formed by subjecting the trenches 150 to electroless plating and electroplating. Particularly, a plating layer protruding from the upper surface of the insulating base 100 is removed after the electroplating process has been performed, so that the connection pattern 170 is completely embedded. The embedded connection pattern 170 is connected to the connection terminals 350 thus obviating a need for an additional redistribution layer and achieving a very reliable connection.

Further, the build-up layer 600 may be formed on the exposed surface of the insulating base 100 or the exposed surface of the insulating layer 200 (FIG. 3). The build-up layer 600 may be formed by applying an additional insulating resin on the exposed surface of the insulating base 100 or the exposed surface of the insulating layer 200, forming via holes using a YAG laser or a CO₂ laser drill, and then performing a semi-additive process. The build-up layer 600 is not necessarily formed on both the exposed surface of the insulating base 100 and the exposed surface of the insulating layer 200, and may be formed on either the exposed surface of the insulating base 100 or the exposed surface of the insulating layer 200. When the build-up layer 600 is additionally formed, the resulting PCB may correspond to products having many I/O pads.

Furthermore, a solder resist layer 700 may be formed on the build-up layer 600 in order to protect an outermost circuit layer. Also, the solder resist layer 700 may include open portions for forming electrical connections to an external device.

FIGS. 4 to 11 are cross-sectional views sequentially showing the process of manufacturing the electronic component-embedded PCB according to the embodiment of the present invention. Below, the description that overlaps the above description is omitted, and it is a description of the present embodiment which makes reference to the appended drawings.

As shown in FIGS. 4 and 5, an electronic component 300 is mounted in a face down manner on one surface of an insulating base 100. Specifically, the electronic component 300 is mounted on the insulating base 100 using a vacuum adsorption head 110 (FIG. 4). In order to stably mount the electronic component 300 on the insulating base 100, an adhesive layer 500 is applied on one surface of the insulating base 100, and then the electronic component to 300 is adhered on the adhesive layer 500 (FIG. 5). As such, the adhesive layer 500 may be formed of a solid die attach film or a liquid adhesive. Meanwhile, before the present procedure, in order to prevent the insulating base 100 from warping during the manufacturing process, the insulating base 100 may be mounted on a carrier 130 so as to expose the one surface of the insulating base 100 on which the electronic component 300 is to be mounted.

Next, as shown in FIG. 6, an insulating layer 200 is formed on one surface of the insulating base 100 so that the electronic component 300 is embedded therein. As the insulating layer 200 is formed on the insulating base 100, the electronic component 300 is embedded in the PCB. Also, in order to ensure the structural stability of the PCB, the insulating layer 200 may be formed on the insulating base 100 so that a thickness T ranging from the active surface of the electronic component 300 to the exposed surface of the insulating base 100 (which is the exposed surface in a state in which the carrier 130 is removed) is equal to a thickness T ranging from the surface opposite the active surface to the exposed surface of the insulating layer 200. Herein, as mentioned above, the equal thicknesses do not mean that their mathematical values are completely identical to each other but are used in a sense which takes into account slight changes in thickness due to process error and so on occurring in the manufacturing process.

Next, as shown in FIG. 7, the carrier 130 is removed. Specifically, because the formation of the insulating layer 200 in the previous procedure ensures supportability sufficient for preventing warping of the insulating base 100, the carrier 130 is no longer needed. Furthermore, because trenches 150 should be processed in the insulating base 100 in a subsequent procedure, the carrier 130 should be removed in the present procedure. The present procedure is optionally performed only when the carrier 130 is used.

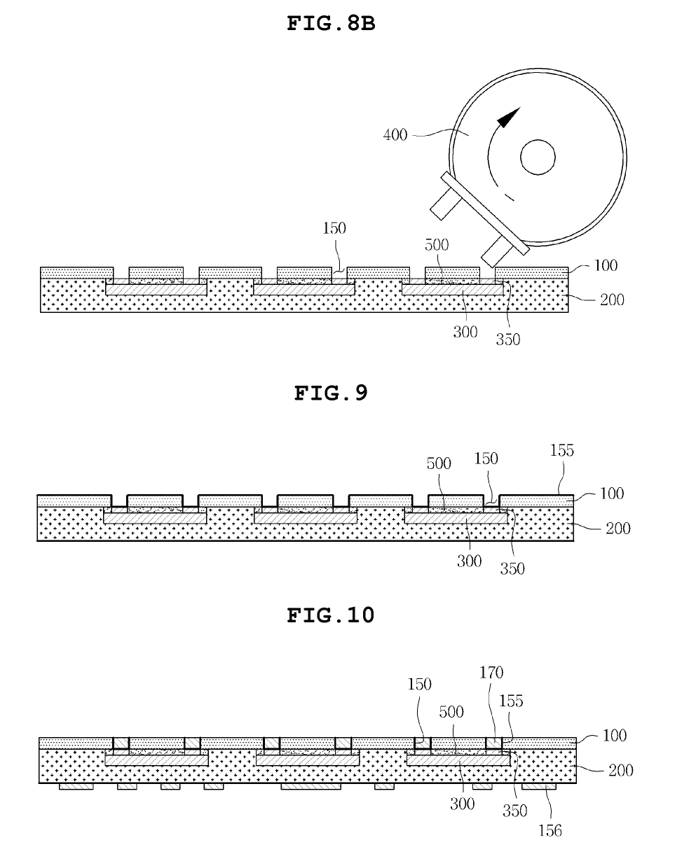

Next, as shown in FIGS. 8A and 8B, the trenches 150 are processed in the insulating base 100 to expose the connection terminals 350 of the electronic component 300. The trenches 150 may be formed using an imprinting process or a laser process (e.g. Nd—YAG (Neodymium-doped Yttrium Aluminum Garnet)). In the case where a flat mold is used in the imprinting process, such a flat mold is not easy to strip from the insulating base 100. Thus, a cylindrical mold 400 which is easy to strip is used to form the trenches 150. The to trenches 150 are processed by rotating the cylindrical mold 400 so as to expose a plurality of connection terminals 350 (FIGS. 8A and 8B).

Next, as shown in FIGS. 9 and 10, the trenches 150 are subjected to plating, so that a connection pattern 170 which is connected to the connection terminals 350 is formed and embedded in the trenches. Specifically, an electroless plating layer 155 is formed (FIG. 9), after which the trenches 150 are subjected to an electroplating process, thus forming the connection pattern 170 embedded in the trenches (FIG. 10). Particularly, portions of the electroless plating layer 155 on which the electroplating layer is not formed are removed through etching, and the electroplating layer protruding from the upper surface of the insulating base 100 is removed, thus completely embedding the connection pattern 170. The connection pattern 170 thus embedded may be connected to the connection terminals 350 thus obviating a need for an additional redistribution layer and achieving a very reliable connection. Using the plating process when the connection pattern 170 is formed, a circuit layer 156 may also be formed on the exposed surface of the insulating layer 200 thus simplifying the manufacturing process.

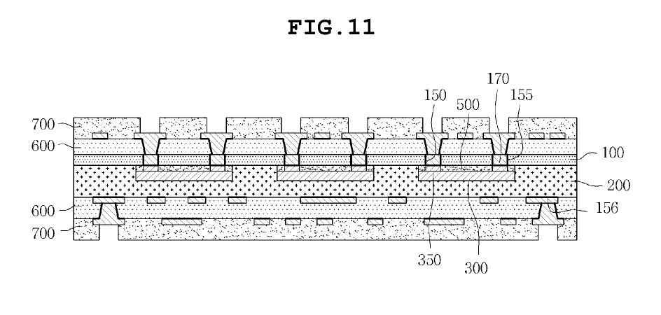

Next, as shown in FIG. 11, a build-up layer 600 is formed on the exposed surface of the insulating base 100 or the exposed surface of the insulating layer 200. The build-up layer 600 is formed by applying an additional insulating resin on the exposed surface of the insulating base 100 or the exposed surface of the insulating layer 200, forming via holes using a YAG laser or a CO₂ laser drill, and then performing a semi-additive process. The build-up layer 600 is not necessarily formed on both the exposed surface of the insulating base 100 and the exposed surface of the insulating layer 200, but may be formed on either the exposed surface of the insulating base 100 or the exposed surface of the insulating layer 200. The additional formation of the build-up layer 600 enables the resulting PCB to correspond to products having many I/O pads.

Also, a solder resist layer 700 may be formed on the build-up layer 600 in order to protect an outermost circuit layer. The solder resist layer 700 may include open portions for forming electrical connections to an external device.

As described hereinbefore, the present invention provides an electronic component-embedded PCB and a method of manufacturing the same. According to the present to invention, an embedded connection pattern is finely formed by an imprinting process and is connected to connection terminals of the electronic component, thus obviating a need for an additional redistribution layer and reducing the manufacturing cost.

Also, according to the present invention, there is no need to process a cavity for disposing the electronic component in an insulating layer, thus producing no voids, simplifying the manufacturing process and reducing the manufacturing cost.

Also, according to the present invention, because of the use of the imprinting process, the connection pattern can be finely formed so as to correspond to the connection terminals of the electronic component. After the formation of the embedded electronic component, a build-up layer can be further formed, whereby the resulting PCB can correspond to products having many I/O pads.

Also, according to the present invention, the imprinting process is performed using a cylindrical mold which is easy to strip compared to when using a conventional flat mold, thus improving the quality of trenches, resulting in very reliable connections between the connection pattern loaded in the trenches and the connection terminals of the electronic component.

Although the embodiments of the present invention regarding the electronic component-embedded PCB and the method of manufacturing the same have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. An electronic component-embedded printed circuit board, comprising:
an insulating base;
an insulating layer formed on one surface of the insulating base;
an electronic component embedded in the insulating layer so that an active surface of the electronic component having a connection terminal faces the insulating base;
a trench formed in the insulating base to expose the connection terminal; and
a connection pattern formed and embedded in the trench.

2. The printed circuit board as set forth in claim 1, wherein the trench is formed by rotating a cylindrical mold.

3. The printed circuit board as set forth in claim 1, further comprising an adhesive layer formed between the insulating base and the electronic component.

4. The printed circuit board as set forth in claim 3, wherein the adhesive layer comprises a solid die attach film or a liquid adhesive.

5. The printed circuit board as set forth in claim 1, further comprising a build-up layer formed on an exposed surface of the insulating base or an exposed surface of the insulating layer.

6. The printed circuit board as set forth in claim 1, wherein a thickness ranging from the active surface of the electronic component to an exposed surface of the insulating base is equal to a thickness ranging from a surface opposite the active surface to an exposed surface of the insulating layer.

7. A method of manufacturing an electronic component-embedded printed circuit board, comprising:
(A) mounting an electronic component in a face down manner on one surface of an insulating base;
(B) forming an insulating layer on the one surface of the insulating base so that the electronic component is embedded;
(C) processing a trench in the insulating base so as to expose a connection terminal of the electronic component; and
(D) subjecting the trench to plating, so that a connection pattern which is connected to the connection terminal is formed and embedded in the trench.

8. The method as set forth in claim 7, wherein the processing the trench in (C) is performed by rotating a cylindrical mold.

9. The method as set forth in claim 7, wherein the mounting the electronic component in (A) is performed by forming an adhesive layer on the one surface of the insulating base and then adhering the electronic component to the adhesive layer.

10. The method as set forth in claim 9, wherein the adhesive layer comprises a solid die attach film or a liquid adhesive.

11. The method as set forth in claim 7, further comprising forming a build-up layer on an exposed surface of the insulating base or an exposed surface of the insulating layer, after (D).

12. The method as set forth in claim 7, further comprising forming the insulating base on a carrier so as to expose the one surface of the insulating base, before (A), and removing the carrier, after (B).

13. The method as set forth in claim 7, wherein the forming the insulating layer in (B) is performed by applying the insulating layer on the insulating base so that a thickness ranging from an active surface of the electronic component to an exposed surface of the insulating base is equal to a thickness ranging from a surface opposite the active surface to an exposed surface of the insulating layer.
